(19) United States
(12) Patent Application Publication
(10) Pub. No.: US 2014/0266268 A1
(43) Pub. Date: Sep. 18, 2014

(54) System and Circuit for Self-Adjusting Impedance Measurement

(71) Applicant: TransTech Systems, Inc., Schenectady, NY (US)

(72) Inventor: Frank H. Lipowitz, Rexford, NY (US)

(73) Assignee: TransTech Systems, Inc., Schenectady, NY (US)

(21) Appl. No.: 14/206,475

(22) Filed: Mar. 12, 2014

Related U.S. Application Data
(60) Provisional application No. 61/787,484, filed on Mar. 15, 2013.

(51) Int. Cl. G01R 27/02

(52) U.S. Cl. CPC G01R 27/02
USPC 324/709

(57) ABSTRACT

Various embodiments of the invention relate generally to the measurement of the impedance of materials, electronic devices, or components over a range of frequencies, with a system for self-adjusting an input transmit signal and/or a reference signal to produce a measured signal within a desired range of the electronic measuring components over the frequency range based upon the value of the measured signal.

### CROSS-REFERENCE TO RELATED APPLICATION

This utility application claims the benefit of U.S. Provisional Patent Application Ser. No. 61/787,484, filed on Mar. 15, 2013, which is hereby incorporated by reference in its entirety.

### TECHNICAL FIELD

The invention relates generally to the measurement of the impedance of materials, electronic devices and/or components.

### BACKGROUND

The use of impedance to measure the characteristics of construction, manufacturing and biological materials using impedance spectroscopy and impedance tomography is increasing. However, conventional approaches are still deficient in a number of aspects.

### SUMMARY

The systems, circuits (and methods and computer program products) of the present disclosure relate the measurement of the impedance of materials, electronic devices and/or components over a range of frequencies, with provisions for the self-adjustment of the transmit and reference signals to produce a measured signal within a desired (e.g., optimal) range of the electronic measuring components, e.g., over the frequency range, based upon the value of the measured signal. The present subject matter provides for an electronic circuit which generates the transmit signal and the reference signal over a range of frequencies. The transmit signal is sent to a material (or device) (also referred to as a material under test, or MUT). The strength (and/or magnitude) of the transmitted signal across the material (or MUT) is then compared to the desired (e.g., optimal) signal strength or the electronic components measuring the strength or magnitude and phase of the signal. If the measured signals fall outside the desired operating range of the measuring electronic components, the transmit and reference signals are adjusted in strength to enhance the compatibility of the measured signal to the input range of the electronic measuring components for signal strength or magnitude and phase. The resultant circuit design is compatible in terms of cost and size to be used with field instrumentation.

Various particular embodiments include a system having: a signal generator; an amplifier connected with the signal generator; a reference signal attenuation device connected with the amplifier; a signal level detector connected to the reference signal attenuation device; a phase detector connected to the reference signal attenuation device; and at least one computing device connected to the phase detector, the level detector, and the signal generator, the at least one computing device configured to: initiate a transmit signal to a material under test; and determine a complex impedance response of the material under test based upon a return signal from the material under test.

Various other particular embodiments include a system having: a signal generator; at least one current-to-voltage converter connected with the signal generator; an amplifier connected with the at least one current-to-voltage converter; a signal level detector connected to the amplifier; a phase detector connected to the amplifier; and at least one computing device connected to the phase detector, the level detector, and the signal generator, the at least one computing device configured to: initiate a transmit signal to a material under test; and determine a complex impedance response of the material under test based upon a return signal from the material under test.

Additional particular embodiments include a circuit for self-adjusting impedance measurement, the circuit including: a signal generator; an amplifier connected with the signal generator; a reference signal attenuation device connected with the amplifier; a signal level detector connected to the reference signal attenuation device; a phase detector connected to the reference signal attenuation device; at least one computing device connected to the phase detector, the level detector, and the signal generator, the at least one computing device configured to: initiate a transmit signal to a material under test; and determine a complex impedance response of the material under test based upon a return signal from the material under test; a first fixed resistor coupled to the reference signal attenuation device and ground; and a second fixed resistor coupled to the signal level detector, the phase detector, and ground.

### BRIEF DESCRIPTION OF THE FIGURES

FIG. 1 is a graphical depiction of the dielectric spectrum of an idealized material according to the prior art;

FIG. 2 is a graphical depiction of the dielectric spectrum of a real material (soil) according to the prior art;

FIG. 3 is a schematic illustration of an auto-balancing-bridge circuit used in impedance analyzers according to prior art;

FIG. 4 is a schematic illustration of the circuit of an AD5933/5934 impedance converter chip according to prior art;

FIG. 5 is a schematic illustration of a custom impedance measuring circuit according to prior art;

FIG. 6 is a schematic illustration of a system according to various embodiments of the present subject matter;

FIG. 7 is an illustration of a system according to various alternate embodiments of the present subject matter;

FIG. 8 is a logic flow diagram showing processes according to various embodiments of the present subject matter;

FIG. 9 is a logic flow diagram showing processes according to various embodiments of the present subject matter;

FIG. 10 shows an illustrative environment according to various embodiments of the present subject matter.

FIG. 11 is a data graph illustrating change in voltage or signal magnitude from a circuit board with a pure resistive load, according to various embodiments.

FIG. 12 is a data graph illustrating change in voltage or signal magnitude from the circuit in FIG. 12 with a pure capacitive load

### DETAILED DESCRIPTION

Various embodiments of the disclosure relate generally to systems and circuits for the measurement of the impedance of materials (or electronic devices or components), over a range of frequencies. The systems and circuits include components for the self-adjustment of the input transmit and reference signals to produce a measured signal within a desired (e.g., optimal) range of the electronic measuring components over the frequency range based upon the value of the measured signal.

The use of impedance to measure the characteristics of construction, manufacturing and biological materials using impedance spectroscopy and impedance tomography is increasing. The subject matter of U.S. Pat. No. 5,900,736, U.S. Pat. No. 6,414,497 and U.S. Pat. No. 7,219,024; US Patent Publication No. 2009/0270756 and US Patent Publication No. 2012/0130212; and Provisional U.S. Patent Application No. 61/647,848 (filed on May 16, 2012), Provisional U.S. Patent Application No. 61/703,488 (filed on Sep. 20, 2012) and Provisional U.S. Patent Application No. 61/784,363 (Attorney Dkt. No. TRAN-0025-PV, filed on Mar. 14, 2013), describe some impedance-related techniques for determining characteristics of materials, and are each incorporated by reference herein in their entirety. In making impedance measurements using devices and applications, the conventional options to generate the signals and to measure the complex impedance have been limited to impedance analyzers, such as the Agilent 4294A (available from Agilent Technologies, Santa Clara, Calif., United States) and Solartron 1260A (available from Solartron Analytical, a subsidiary of Ametek, Inc., Berwyn, Pa., United States), integrated circuits, such as AD 5933/5934 (available from Analog Devices, Norwood, Mass., United States), or dedicated custom circuits. The use of impedance analyzers for the development and testing of impedance measurement devices may be acceptable, but these units are associated with large costs, and are also physically large (222 mm (8.75 in) high, 459 mm (18.1 in) wide and 573 mm (22.6 in) deep) and heavy (25 kg (55 lbs)). In order to overcome some of the issues related to the use of an impedance analyzer and the development of a custom circuit, a prior approach involved developing an integrated circuit impedance converter, AD 5933/5934 (available from Analog Devices, Norwood, Mass., United States). The costs and size of these impedance converter chips/devices were significantly less than the conventional impedance converter chips/devices at that time. However, these devices (e.g., AD 5933/5934) have limitations, as further discussed herein. For the above-noted conventional devices (and other related conventional devices), the approach has been to develop customized circuits, however, even utilizing these customized circuits, the conventional approaches fail to successfully identify characteristics of complex materials.

Turning to the characteristics of materials that the will be the targets of the impedance measuring devices, in FIG. 1, the impedance characteristics of an ideal dielectric material is shown as a function of frequency. As is known in the art, an ideal dielectric material is one in which an electric field may be applied without any energy loss.

As shown in the graphical diagram of FIG. 1, “relaxations” exist in the spectrum, where the energy from the input signal is absorbed by various physical sinks Starting at the lowest frequencies, the most common relaxations are: ionic, dipole, atomic and electronic. Ionic relaxation comprises ionic conductivity and interfacial and space charge relaxation. Dipole relaxations arise from permanent and induced dipoles aligning to an electric field. Atomic relaxation is observed when the nucleus of the atom reorients in response to the electric field. The electronic relaxation process occurs in a neutral atom when the electric field displaces the electron density relative to the nucleus it surrounds. These relaxations can cause significant changes in the impedance values of the ideal dielectric, e.g., by orders of magnitude, from the ideal state. When a material (e.g., dielectric material) contains water, a highly polar molecule, there are additional relaxations, as shown in the relaxation graph according to the prior art (dielectric spectrum of a real material, soil, after Hilhorst transformation (Hilhorst, M. A. (1998), “Dielectric Characterization of Soil,” Wageningen, Netherlands)) and shown in FIG. 2. These relaxations depict how the water molecule bonds with other materials (molecules) in the sample. For soils, e.g., the size distribution of the solids can have a significant impact on the amount of the relaxation and the frequency at which that relaxation occurs.

As opposed to the response of a vacuum, the response of non-ideal materials to external fields generally depends on the frequency of the field. This is demonstrated in the example frequency graph of FIG. 1. This frequency spectroscopy is due to the fact that a material's polarization does not respond instantaneously to an applied field. The response is causal (arising after the applied field), which can be represented by a phase difference. For this reason, permittivity is often treated as a complex function (since complex numbers allow specification of magnitude and phase) of the (angular) frequency of the applied field ω, ∈→\hat{∈}(ω). The characterization of permittivity therefore becomes:

D₀e^{-iωt}=\hat{∈}(ωE₀e^{-iωt}, (Equation 1)

where D₀ and E₀ are the amplitudes of the displacement and electrical fields, respectively, i is the imaginary unit, i²=−1.

The response of a medium to static electric fields can also be described by the low-frequency limit of permittivity, also called the static permittivity ∈ₛ (also ∈DC):

$${ɛ}_{s} = {lim}_{ω \to 0} \hat{ɛ} ( ω ) . \qquad ( Equation 2 )$$

At the high-frequency limit, the complex permittivity is commonly referred to as ∈_{∞}. The static permittivity can form a good approximation for alternating fields of low frequencies, and as the frequency increases, a measurable phase difference δ emerges between D and E. The frequency at which the phase shift becomes noticeable depends on temperature and the details of the medium. For moderate field strength (E₀), D and E remain proportional, and:

$$\hat{ɛ} = \frac{{D}_{0}}{{E}_{0}} = \vert ɛ \vert {e}^{i δ} . \qquad ( Equation 3 )$$

As the response of materials to alternating fields is characterized by a complex permittivity, it is natural to separate its real and imaginary parts, which is calculated by:

$$\hat{ɛ} ( ω ) = {ɛ}^{′} ( ω ) + i {ɛ}^{″} ( ω ) = \frac{{D}_{0}}{{E}_{0}} ( cos δ + i sin δ ) . \qquad ( Equation 4 )$$

Where: ∈″ is the imaginary part of the permittivity, which is related to the dissipation (or loss) of energy within the medium; and, ∈′ is the real part of the permittivity, which is related to the stored energy within the medium.

It may be helpful to realize that the choice of sign for time-dependence, exp (−iωt), dictates the sign convention for the imaginary part of permittivity. The signs used here correspond to those commonly used in physics, whereas for the engineering convention one should reverse all imaginary quantities.

The complex permittivity is usually a complicated function of frequency w, since it is a superimposed description of dispersion phenomena occurring at multiple frequencies. The dielectric function ∈(ω) has poles only for frequencies with positive imaginary parts. However, in the narrow frequency ranges sometimes observed, the permittivity can be approximated as frequency-independent or by model functions.

The fact that there are such large variations of the impedance values over a wide frequency range can create design problems using the conventional approaches to the measurement of impedance. A recent conventional version of impedance analyzers, the 4294A, from Agilent uses an “Auto-Balancing-Bridge” method (shown in the schematic system diagram of FIG. 3), which is described in U.S. Pat. No. 7,307,430 and U.S. Pat. No. 6,956,380. This impedance analyzer provides the values of impedance, phase angle, resistance, inductance and other electrical parameters based on the measurement of the change of the signal energy (voltage, magnitude) and phase shift of the input signal and output signal. The conventional AD5933/5934 circuit approach is different from the above-noted “Auto-Balancing-Bridge” conventional approach in that the values of impedance and the phase angle are determined by sampling the value of the voltage (Vin in FIG. 4), which is then processed as a discrete Fourier transform (DFT) by an on-board Digital Signal Processor (DSP) engine. The DFT algorithm returns a real (R) and imaginary (I) data-word at each output frequency.

In this conventional approach, the magnitude and phase are then computed using the following two equations:

Magnitude=(R₂+I₂)½

Phase=tan−1(I/R)

From these terms (magnitude and phase), various impedance terms may be calculated as described below. A circuit diagram illustrating a circuit according to another embodiment of the prior art is shown in FIG. 5. This circuit provides the direct measurement of the magnitude and phase angle by comparing the reference signal to the transmitted signal in a comparator. As for the conventional AD5933 system, the magnitude and phase may be used to calculate various impedance values.

In order to accommodate the large variations in the measurements over a range of frequencies, the resistor across which the voltage across the material or device under test is measured. In FIG. 3, the voltage is noted as V₂ and the resistors are noted as Rr. As the frequency is changed, the value of the resistance is changed. In the conventional 4294A system, there is a series of four range resistors (50 ohms, 400 ohms, 3,200 ohms and 25,600 ohms). There is a programmed process which controls which range resistor is used. The conventional AD5933/5934 system also uses a resistor across which the voltage of the material or device under test is measured. In FIG. 4, the voltage is labeled as Vin, and the resistor as Mb. The resistor is user-selected, and is connected to the conventional AD5933/5934 system. Because there is no provision for the value of the resistor to change, the range of frequencies that may be scanned using this conventional system is limited to those which produce a value of Vin that falls within the input range of the first amplifier integrated into the AD5933/5934 system's chip. In contrast to the above-noted conventional approaches, the systems and circuits according to various embodiments of the disclosure utilize three values of resistance that are mechanically switched based on the frequency being scanned. Based upon data gained about the material being tested, the approximate magnitude of the signal at a given frequency can be determined by the comparator (e.g., at least one computing device, FIG. 10). This allows the switch among resistors to maintain the comparator input signal within the range of the comparator.

Of the conventional approaches described herein, only the impedance analyzer (FIG. 3) uses the measured response to select the range resistors. This is accomplished with a costly and cumbersome laboratory instrument that is inappropriate for use with any type of field instrumentation. The other conventional approaches use various types of range resistor switching based on a priori knowledge of the expected range of the measurements.

Various embodiments of the present subject matter provide a circuit that can be used in field instrumentation, in terms of size and cost, that adjusts the measured voltage across the material or device under test over a range of frequencies to be within the range of the measuring device based upon the value of the voltage measured.

In making measurements and interpreting aspects of the complex impedance, it can be helpful to define terms that may be calculated from the output of the measurement device which are the magnitude of the power between the reference signal and the transmit signal that is passed through the material or device under test and the transmitted signal, defined as magnitude, m, and the phase angle, δ, shift between the reference signal and the transmit signal which occurs as the signal passes through the material or device under test. Impedance (Z) is represented mathematically as a complex relation consisting of a real part, resistance, and an imaginary part, reactance:

Z=R+iX;

Z=the complex value of Impedance;

R=m*cos δ, the Resistance; and

X=m*sin δ, the Reactance.

Resistance, R, is a material's opposition to the flow of electric current.

Reactance, X, is a material's opposition to alternating current due to capacitance (capacitive reactance) and/or inductance (inductive reactance).

Susceptance (B) is a complementary representation of the reactance in the term admittance and is defined mathematically as:

B=1/X.

The Susceptance may be computed from the measured properties as follows:

B=sin δ/m, the Susceptance.

Admittance (Y) is a complex quantity which is the inverse of Impedance, and results in the definition of the terms of Conductance and Susceptance:

Y=1/Z=G+iB; and

Y=the Admittance.

The Conductance may be computed from the measured properties as follows:

G=cos δ/m, the Conductance.

Various embodiments of the disclosure overcome the shortcoming of the current state of art in measuring the impedance of a material (or device) under test during field measurements. As described herein, the conventional impedance analyzer (shown in FIG. 3) can determine the impedance of a material (or device) under test. However, it is too bulky (e.g., heavy) and costly to be utilized in a portable device (e.g., a handheld impedance analyzer). The other conventional approaches described herein are based on integrated circuit chips such as the conventional AD5933/5934 (FIG. 4) and conventional dedicated custom circuits (FIG. 5). At least one issue with approaches other than the conventional impedance analyzer (FIG. 3) is that these approaches require a priori knowledge of the range of the values of the measured impedance and the resulting signal strength, so that a reference (or sense) resistor can be selected to match the resultant measured voltage with the input range of the electronic device measuring that voltage or the phase shift. In contrast, the systems and circuits according to various embodiments adjust the transmit and the reference signals based upon the measurement of the signal strength across the material or device under test so that the measurement response may be optimized over the range of frequencies used in the test.

Various embodiments of the disclosure are presented as a circuit board with the functions performed by individual electronic components. However, it is will be understood by those skilled in the art that the entire circuit, or portions of the circuit, may be fabricated as an integrated circuit chip. A system according to various embodiments of the present subject matter is presented schematically in FIG. 6.

Referring to embodiments of the present disclosure illustrated in the system (circuit) diagram of FIG. 6, the circuit board or (integrated circuit assembly) 100 includes a plurality of components. The circuit board 100 includes a sine wave signal generator 101 including a Direct Digital Synthesizer (DDS) with a single output (e.g., such as AD991). The differential sinusoidal wave signal at a selected test frequency can be passed into a multi-channel amplifier 102 (e.g., such as AD8024), to generate an amplified single-ended transmit signal and a single-ended reference signal. The transmit signal can then be passed to the material (or device) under test 104. The strength or magnitude of the signal from the material (or device) under test can then be measured across a fixed reference resistor 105 by an absolute level detector 107 (e.g., such as AD8310). The signal from the material (or device) under test can be transmitted to a phase detector 108, (e.g., such as AD8302), where it is compared to the phase from the reference signal. The reference signal is passed through a reference signal attenuation component 103 and the signal strength (and/or magnitude) can be measured across a fixed reference resistor 109 by an absolute level detector 106 (e.g., such as AD8310). The outputs of the absolute level detector 106, absolute level detector 107 and phase detector 108 can be entered into a microprocessor 110 (e.g., at least one computing device) which encodes the analog signals to digital signals. A separate analog-to-digital component may be used prior to input to the microprocessor. Comparison of the signal from absolute level detector 107 to optimal design criteria for the absolute level detector 107 in the microprocessor 110 (e.g., at least one computing device) can result in an adjustment to the magnitude of the signal from sine wave signal generator 101 such that the signal entering absolute level detector 107 is in its desired (e.g., optimal) range. The signal from absolute level detector 106 is then compared to optimal design criteria for absolute level detector 106 in the microprocessor. This can result in an adjustment to the reference signal attenuation in reference signal attenuation component 103 such that the reference signal to absolute level detector 106 is within its desired (e.g., optimal) range. The microprocessor 110 can then output the data and repeat the above-noted process for another frequency (e.g., adjacent frequency) in a range of frequencies.

In the various embodiments shown and described with respect to FIG. 6, the return signals all pass through the same signal generator 101 and amplifier 102, the only source of phase variation is the material or device under test 104. However, other embodiments (including distinct configurations) are also possible (e.g., as shown in the system/circuit diagram of FIG. 7). In these embodiments (FIG. 7), there could be a phase shift in the return signal due to the variability of the conversion and amplification components. In these cases of inherent phase distortion, the phase distortion will be constant and may be accommodated by a calibration of the circuit with test components such as resistors with selected values to cover the range of amplification.

Referring to the various alternate embodiments of the present subject matter illustrated in the system (circuit) diagram of FIG. 7, a circuit board (integrated circuit assembly) 200 includes a plurality of components described herein. Assembly 200 can include a sine wave signal generator (e.g., dual-channel sine wave signal generator) 201 having of a Direct Digital Synthesizer (DDS) with a dual output (e.g., such as AD9958). The differential sinusoidal wave signals at a selected test frequency are passed into current-to-voltage converters 202 and 203 (e.g., such as AD8012). Referring now only to the reference signal, the reference signal can be amplified in amplifier 204 (e.g., such as AD8012), such that the voltage across the fixed resistor 208 as measured by the absolute level detector 210 (e.g., such as AD8310), is at the desired (e.g., optimal) value for the range criteria of the detector. The output of absolute level detector 210 can be directed to a microprocessor (e.g., at least one computing device) 213, where it is converted from an analog signal to a digital signal. In some embodiments, a separate analog-to digital component may be used prior to input to the microprocessor 213 for all three signals. The reference signal can also be transmitted to a phase detector 212 (e.g., such as AD8302). The transmit signal can be transmitted to the amplifier 205 (e.g., such as AD8012). From the output of the amplifier 205, the signal can be transmitted to (passed into/through) the material (or device) under test (MUT). The voltage of the output from the material (or device) under test can be measured by an absolute level detector 211 (e.g., such as AD8310), across the fixed resistor 209. The output of absolute level detector 211 can be transmitted to the microprocessor 213, where it is converted from an analog signal to a digital signal. The signal from the material (or device) under test can also be transmitted to a phase detector 212, where it is compared to the phase from the reference signal. The output of the phase detector 212 can be directed to the microprocessor 213 where it is converted from an analog signal to a digital signal. Comparison of the signal from the absolute level detector 211 to the desired (e.g., optimal) design criteria for the absolute level detector 211 in the microprocessor 213 can result in an adjustment to the magnitude of the signal from amplifier 205, such that the signal entering absolute level detector 211 is in its desired (e.g., optimal) range. The microprocessor 213 can then output the data and repeat the above-noted process for another frequency (e.g., adjacent frequency) in a range of frequencies.

The actual value of the magnitude, the difference in strength between the reference signal and the transmit signal, includes the differential values of the attenuation and amplification called magnitude in the following. In the various embodiments described with reference to FIG. 6, the actual magnitude is the difference between the value of the reference signal measured by absolute level detector 106 and the transmit signal measured by absolute level detector 107, plus the level of attenuation provided by reference signal attenuation component 103. The phase angle is the value measured by phase detector 108. In various alternative embodiments described with reference to FIG. 7, the actual magnitude is the difference between the value of the reference signal measured by absolute level detector 210 and the transmit signal measured by absolute level detector 211, less the difference in the level of amplification provided by amplifier 205 and amplifier 204. The phase angle is the value measured by phase detector 212, which can be corrected for the phase shift induced by the variability of the conversion and amplification components. The phase shift distortion can be constant and may be accommodated by a calibration of the circuit with test components such as resistors with selected values to cover the range of amplification.

As described herein, various aspects can include computer-implemented methods, systems and computer program products for performing a series of functions. The various embodiments of the invention include a signal generator operably connected to other electronic components and to the material or device under test (e.g., hard-wired). The various embodiments of the invention can further include at least one computing device 1002, e.g., including a microprocessor 110 (FIG. 6, FIG. 10) operably connected with the signal generator and other electronic components (e.g., wirelessly and/or hard-wired) and the material or device under test (e.g., wirelessly and/or hard-wired, or simply via common connection with the signal generator and other electronic components). The computing device included in the various embodiments of the invention maybe be operably connected with other computing devices (e.g., wirelessly and/or hard-wired).

FIG. 8 shows a flow diagram depicting processes associated with the system/circuit diagram in FIG. 6, according to various embodiments; and FIG. 9 shows a flow diagram depicting processes associated with the system/circuit diagram in FIG. 7, according to various embodiments. FIGS. 6-9 relate at least in part to the environment shown in FIG. 10, and as such, description of that environment is provided prior to description of the flow diagrams of FIGS. 8 and 9 herein.

FIG. 10 depicts an illustrative environment 1000 for self-adjusting impedance calculations according to various embodiments. To this extent, the environment 1000 includes a computer system 1002 that can perform a process described herein in order to self-adjust measurement parameters to detect an impedance response of a material. In particular, the computer system 102 is shown as including a self-adjusting impedance program 1030, which makes computer system 1002 operable to self-adjust measurement parameters to detect an impedance response of a material by performing any/all of the processes described herein and implementing any/all of the embodiments described herein.

The computer system 1002 is shown including a processing component 1004 (e.g., one or more processors), a storage component 1006 (e.g., a storage hierarchy), an input/output (I/O) component 1008 (e.g., one or more I/O interfaces and/or devices), and a communications pathway 1010. In general, the processing component 1004 executes program code, such as the self-adjusting impedance program 1030, which is at least partially fixed in the storage component 1006.

While executing program code, the processing component 1004 can process data, which can result in reading and/or writing transformed data from/to the storage component 1006 and/or the I/O component 1008 for further processing. The pathway 1010 provides a communications link between each of the components in the computer system 1002. The I/O component 1008 can comprise one or more human I/O devices, which enable a human user 1012 to interact with the computer system 1002 and/or one or more communications devices to enable a system user 1012 to communicate with the computer system 1002 using any type of communications link. To this extent, the self-adjusting impedance program 1030 can manage a set of interfaces (e.g., graphical user interface(s), application program interface, etc.) that enable human and/or system users 1012 to interact with the self-adjusting impedance program 1030. Further, the self-adjusting impedance program 1030 can manage (e.g., store, retrieve, create, manipulate, organize, present, etc.) data, such as level detector data (e.g., from one or more level detectors described herein) 1040, phase detector data (e.g., from one or more phase detectors described herein) 1042, etc., using any solution. In various embodiments, the self-adjusting impedance program 1030, via the computer system 1002, is operably connected (e.g., via wireless and/or hard-wired connection) to the circuit board/IC chip 100 and/or the circuit board/IC chip 200, described further herein. In some cases, the processing component 1004 can include the microprocessor 110 and/or 213, and can be configured to receive instructions from the self-adjusting impedance program 1030 to perform various processes described herein.

In any event, the computer system 1002 can comprise one or more general purpose computing articles of manufacture (e.g., computing devices) capable of executing program code, such as the self-adjusting impedance program 1030, installed thereon. As used herein, it is understood that “program code” means any collection of instructions, in any language, code or notation, that cause a computing device having an information processing capability to perform a particular function either directly or after any combination of the following: (a) conversion to another language, code or notation; (b) reproduction in a different material form; and/or (c) decompression. To this extent, the timing quantity self-adjusting impedance program 1030 can be embodied as any combination of system software and/or application software.

Further, the self-adjusting impedance program 1030 can be implemented using a set of modules 1032. In this case, a module 1032 can enable the computer system 1002 to perform a set of tasks used by the self-adjusting impedance program 1030, and can be separately developed and/or implemented apart from other portions of the self-adjusting impedance program 1030. As used herein, the term “component” means any configuration of hardware, with or without software, which implements the functionality described in conjunction therewith using any solution, while the term “module” means program code that enables the computer system 1002 to implement the functionality described in conjunction therewith using any solution. When fixed in a storage component 1006 of a computer system 1002 that includes a processing component 1004, a module is a substantial portion of a component that implements the functionality. Regardless, it is understood that two or more components, modules, and/or systems may share some/all of their respective hardware and/or software. Further, it is understood that some of the functionality discussed herein may not be implemented or additional functionality may be included as part of the computer system 1002.

When the computer system 1002 comprises multiple computing devices, each computing device may have only a portion of self-adjusting impedance program 1030 fixed thereon (e.g., one or more modules 1032). However, it is understood that the computer system 1002 and self-adjusting impedance program 1030 are only representative of various possible equivalent computer systems that may perform a process described herein. To this extent, in other embodiments, the functionality provided by the computer system 1002 and self-adjusting impedance program 1030 can be at least partially implemented by one or more computing devices that include any combination of general and/or specific purpose hardware with or without program code. In each embodiment, the hardware and program code, if included, can be created using standard engineering and programming techniques, respectively.

Regardless, when the computer system 1002 includes multiple computing devices, the computing devices can communicate over any type of communications link. Further, while performing a process described herein, the computer system 1002 can communicate with one or more other computer systems using any type of communications link. In either case, the communications link can comprise any combination of various types of wired and/or wireless links; comprise any combination of one or more types of networks; and/or utilize any combination of various types of transmission techniques and protocols.

The computer system 102 can obtain or provide data, such as level detector data 1040 and/or phase detector data 1042 using any solution. For example, the computer system 102 can generate and/or be used to generate level detector data 1040 and/or phase detector data 10422, retrieve level detector data 1040 and/or phase detector data 1042, from one or more data stores, receive level detector data 1040 and/or phase detector data 1042, from another system, send level detector data 1040 and/or phase detector data 1042 to another system, etc.

While shown and described herein as a method and system for self-adjusting impedance detection parameters, it is understood that aspects of the invention further provide various alternative embodiments. For example, in one embodiment, the invention provides a computer program fixed in at least one computer-readable medium, which when executed, enables a computer system to self-adjust impedance detection parameters. To this extent, the computer readable medium includes program code, such as the self-adjusting impedance program 1030 (FIG. 10), which implements some or all of the processes and/or embodiments described herein. It is understood that the term “computer readable medium” comprises one or more of any type of tangible medium of expression, now known or later developed, from which a copy of the program code can be perceived, reproduced, or otherwise communicated by a computing device. For example, the computer-readable medium can comprise: one or more portable storage articles of manufacture; one or more memory/storage components of a computing device; paper; etc.

In another embodiment, the invention provides a method of providing a copy of program code, such as the self-adjusting impedance program 1030 (FIG. 10), which implements some or all of a process described herein. In this case, a computer system can process a copy of program code that implements some or all of a process described herein to generate and transmit, for reception at a second, distinct location, a set of data signals that has one or more of its characteristics set and/or changed in such a manner as to encode a copy of the program code in the set of data signals. Similarly, an embodiment of the invention provides a method of acquiring a copy of program code that implements some or all of a process described herein, which includes a computer system receiving the set of data signals described herein, and translating the set of data signals into a copy of the computer program fixed in at least one computer-readable medium. In either case, the set of data signals can be transmitted/received using any type of communications link.

In still another embodiment, the invention provides a method of generating a system for self-adjusting impedance detection parameters. In this case, a computer system, such as the computer system 1002 (FIG. 10), can be obtained (e.g., created, maintained, made available, etc.) and one or more components for performing a process described herein can be obtained (e.g., created, purchased, used, modified, etc.) and deployed to the computer system. To this extent, the deployment can comprise one or more of: (1) installing program code on a computing device; (2) adding one or more computing and/or I/O devices to the computer system; (3) incorporating and/or modifying the computer system to enable it to perform a process described herein; etc.

Referring to FIG. 6 and FIG. 8, with continuing reference to FIG. 10, the at least one computing device (e.g., including microprocessor 110) is configured to perform the following processes, via connection (e.g., wireless and/or hard-wired) with the circuit board/IC chip 100 (not necessarily in this order):

P1: instruct the signal generator (e.g., sine wave generator 101) to produce a single (e.g., sinusoidal) wave form at a selected test frequency;

P2: multi-channel amplifier 102 amplifies the signal produced by the signal generator 101, and converts the single wave form signal from a differential signal to two single-end signals: a reference signal and a transmit signal;

P3: the transmit signal is transmitted to the material or device under test 104;

P4: the reference signal (from amplifier 102) is passed to an signal attenuation component 103, which is set at an initial value if the reference signal data is the first data point, or remains at the value of the previous setting;

P5: the reference signal (attenuated or not) is transmitted to the phase detector 108 (P7) and to the reference signal level detector (absolute level detector 106) (P9);

P6: the transmit signal is transmitted and (e.g., via a conventional signal transmitter) passes through the material or device under test and the resulting signal (exit, or return signal) is transmitted to the phase detector 108 (P7) and the transmit signal level detector (absolute level detector 107) (P8);

P7: the phase detector 108 detects and measures the phase shift between the reference signal and the transmit signal after it passes through the material (or device) under test 104;

P8: the transmit signal level detector (absolute level detector) 107 measures the strength of the transmit signal after it passes through the material (or device) under test 104;

P9: the reference signal level detector (absolute level detector) 106 measures the strength of the reference signal;

P10: the signals from the signal level detectors 106, 107 are converted from analog signals to digital signals by an analog-to-digital conversion component (e.g., conventional A-D conversion component) or within the microprocessor (e.g., at least one computing device) 110, where the values of the received signals are compared to the desired input values to the signal level detector 106, 107 in order to determine if the levels of attenuation or amplification should be modified;

P11: if the levels of attenuation or amplification require modification (based upon the comparison in P10, if a deviation from the desired level(s) exists), the at least one computing device 110 provides instructions to modify the signal at the signal generator 101 (P1) and/or at the reference signal attenuation component 103 (P4);

P12: if the levels of attenuation or amplification do not require modification (based upon the comparison in P10, if a deviation from the desired level(s) does exist), the computing device 110 provides instructions to the signal generator 101 to initiate the process for the next frequency in the frequency range to be processed (back to process P1); and

P13 (in some embodiments): the at least one computing device 100 (including, e.g., microprocessor 110) provides the comparison/modification data to external databases and/or computing devices for additional processing, recording and/or presentation to user 1012.

Referring to FIG. 7 and FIG. 9, with continuing reference to FIG. 10, regarding the various alternate embodiments of the disclosure, the at least one computing device (e.g., including microprocessor 213) (e.g., FIG. 10) is configured to perform the following processes, via connection with the circuit board/IC chip 200 (not necessarily in this order):

P1A: the at least one computing device 1002 (e.g., including microprocessor 213) instructs the signal generator (e.g., sine wave generator) 201 to produce two sinusoidal wave forms at a selected test frequency (e.g., a single selected test frequency);

P2A: current-to-voltage convertor 203 converts the first generated signal from the signal generator 201 from a differential signal to a single-end-transmit signal;

P3A: current-to-voltage convertor 202 converts the second generated signal from the signal generator 201 from a differential signal to a single-end-reference signal;

P4A: amplifier 205 amplifies the transmit signal;

P5A: amplifier 204 amplifies the reference signal;

P6A: the transmit signal from amplifier 205 is transmitted to the material (or device) under test 206 (e.g., via a conventional signal transmitter);

P7A: the reference signal from amplifier 204 is transmitted to the phase detector 212 (P11A) and to the reference signal level detector (absolute level detector) 210 (P10A);

P8A: the transmit signal passes through the material (or device) under test 206 and the resulting (or, return) signal is transmitted to the phase detector 212 (P11A) and the transmit signal level detector (absolute level detector) 211 (P9A);

P9A: the transmit signal level detector (absolute level detector) 211 measures the strength of the transmit signal after it passes through the material (or device) under test 206;

P10A: the reference signal level detector (absolute level detector) 210 measures the strength of the reference signal;

P11A: the phase detector 212 detects and measures a phase shift between the reference signal and the transmit signal after the transmit signal passes through the material or device under test 206;

P12A: the signals from the level detectors 210, 211 are converted from analog signals to digital signals by an analog-to-digital conversion component (or within the microprocessor (e.g., computing device)) 213, where the values of the signals are compared to the desired input values to the level detector components 210, 211 in order to determine whether a deviation exits, and if so, that the level of amplification for the transmit signal should be modified.

P13A: if a deviation exists between the signals received from the level detectors 210, 211 and the desired input values for these level detectors 210, 211, the computing device 1000 (e.g., including microprocessor 213) provides instructions to one of the signal generator 201 and/or the amplifier 205 to modify the transmit signal to more closely match the desired transmit signal level at the absolute level detector 211 (P4A);

P14A: if the level of amplification does not require modification (e.g., deviation does not exist in process P12A), the computing device 1002 (including, e.g., microprocessor 213) provides instructions for the signal generator 201 to initiate the process (P1A) for the next frequency (e.g., an adjacent frequency value in a range of frequencies) to be processed;

P15A (in some embodiments): the computing device 1002 (e.g., including microprocessor 213) provides the data about the transmitted/received signals, deviation(s), etc. (e.g., to external databases and/or computing devices) for additional processing, recording and presentation to the user 1012.

Various additional embodiments of the invention include systems, computer program products and computer-implemented methods for self-adjusting impedance calculations. It is understood that some of the processes in the methods for self-adjusting impedance calculations are similar to those described with respect to other embodiments herein. It is further understood that a “computing device” (or multiple “computing devices”) as used herein can refer to one or more hardware and/or software components described with respect to any of the embodiments herein.

### EXAMPLES

FIG. 11 shows a graph 1300 depicting the change in voltage/signal magnitude for a circuit (e.g., circuit in FIG. 6 or FIG. 7) with a pure resistive load, according to various embodiments. As shown in FIG. 11, for a pure resistive load, from zero ohms (short circuit) to 50K ohms, the resultant signal remains in a range of less than 60 db. This occurs over a range of 0.01 MHz to 100 MHz. At the highest resistance and over about 20 MHz, some non-linearity is observed. FIG. 12 shows a data graph 1400 illustrating change in voltage or signal magnitude from the same circuit (FIG. 6 or FIG. 7) as in FIG. 11, but with a pure capacitive load, according to various embodiments. As shown, for a pure capacitive load from 4.7 pF to 470 pF, a hundred fold range, the resultant signal falls within the range of 0 to −60 db. This all occurs through digital processing without the need for a change in a sense resistor.

For the purpose of promoting an understanding of the principals of the invention, reference has been made to the embodiments as illustrated in the drawings and specific language will be used to describe the same. It will nevertheless be understood that no limitation of the scope of the invention is thereby intended, such alterations and further modifications in the illustrated device and such further applications of the principal of the invention as illustrated therein being contemplated as would normally occur to one skilled in the art to which the invention relates.

The description of the principals of the invention uses specific illustrations of electronic component functions. These functions may be separated into multiple electronic components or they may be integrated into fewer electronic components to accomplish the same functionality as would normally occur to one skilled in the art to which the invention relates and to the availability and development of electronic components which perform the identified functions. Changes in the specific electronic components may result to changes in the circuits and logic flow as would normally occur to one skilled in the art to accomplish the same functionality.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. It is further understood that the terms “front” and “back” are not intended to be limiting and are intended to be interchangeable where appropriate.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

We claim:

1. A system comprising:
a signal generator;
an amplifier connected with the signal generator;
a reference signal attenuation device connected with the amplifier;
a signal level detector connected to the reference signal attenuation device;
a phase detector connected to the reference signal attenuation device; and
at least one computing device connected to the phase detector, the level detector, and the signal generator, the at least one computing device configured to:
initiate a transmit signal to a material under test; and
determine a complex impedance response of the material under test based upon a return signal from the material under test.

2. The system of claim 1, wherein the at least one computing device is configured to instruct the signal generator to initiate the transmit signal.

3. The system of claim 1, wherein the at least one computing device is further configured to initiate a reference signal.

4. The system of claim 3, wherein the determining of the complex impedance response includes:
comparing the reference signal and the return signal with a signal detector range; and
modifying a strength of at least one of the transmit signal or the reference signal in response to determining at least one of the reference signal or the return signal deviates from the signal detector range.

5. The system of claim 4, wherein the determining further includes recording at least one of a level of the transmit signal, a level of the reference signal, or a level of the return signal in response to determining the reference signal and the return signal are within the signal detector range.

6. The system of claim 1, wherein the signal level detector includes a plurality of signal level detectors.

7. The system of claim 1, further comprising a fixed resistor coupled to the reference signal attenuation device and ground.

8. The system of claim 1, further comprising a fixed resistor coupled to the signal level detector, the phase detector, and ground.

9. A system comprising:
a signal generator;
at least one current-to-voltage converter connected with the signal generator;
an amplifier connected with the at least one current-to-voltage converter;
a signal level detector connected to the amplifier;
a phase detector connected to the amplifier; and
at least one computing device connected to the phase detector, the level detector, and the signal generator, the at least one computing device configured to:
initiate a transmit signal to a material under test; and
determine a complex impedance response of the material under test based upon a return signal from the material under test.

10. The system of claim 9, wherein the at least one computing device is configured to instruct the signal generator to initiate the transmit signal.

11. The system of claim 9, wherein the at least one computing device is further configured to initiate a reference signal.

12. The system of claim 11, wherein the determining of the complex impedance response includes:
comparing the reference signal and the return signal with a signal detector range; and
modifying a strength of at least one of the transmit signal or the reference signal in response to determining at least one of the reference signal or the return signal deviates from the signal detector range.

13. The system of claim 12, wherein the determining further includes recording at least one of a level of the transmit signal, a level of the reference signal, or a level of the return signal in response to determining the reference signal and the return signal are within the signal detector range.

14. The system of claim 9, wherein the signal level detector includes a plurality of signal level detectors.

15. The system of claim 9, further comprising a fixed resistor coupled to the amplifier and ground.

16. The system of claim 9, further comprising a fixed resistor coupled to the signal level detector, the phase detector, and ground.

17. The system of claim 9, wherein the amplifier includes a plurality of amplifiers.

18. A circuit for self-adjusting impedance measurement, the circuit comprising:
a signal generator;
an amplifier connected with the signal generator;
a reference signal attenuation device connected with the amplifier;
a signal level detector connected to the reference signal attenuation device;
a phase detector connected to the reference signal attenuation device;
at least one computing device connected to the phase detector, the level detector, and the signal generator, the at least one computing device configured to:
initiate a transmit signal to a material under test; and
determine a complex impedance response of the material under test based upon a return signal from the material under test;
a first fixed resistor coupled to the reference signal attenuation device and ground; and
a second fixed resistor coupled to the signal level detector, the phase detector, and ground.

19. The circuit of claim 18, wherein the at least one computing device is configured to:
instruct the signal generator to initiate the transmit signal; and
initiate a reference signal.

20. The circuit of claim 19, wherein the determining of the complex impedance response includes:
comparing the reference signal and the return signal with a signal detector range; and
modifying a strength of at least one of the transmit signal or the reference signal in response to determining at least one of the reference signal or the return signal deviates from the signal detector range.
